(19) United States
(12) Patent Application Publication
(10) Pub. No.: US 2025/0322118 A1
(43) Pub. Date: Oct. 16, 2025

(54) BIM-BASED HANGING BASKET DESIGN METHOD, COMPUTER DEVICE AND COMPUTER-READABLE STORAGE MEDIUM

(71) Applicants: CCCC FIRST HARBOR ENGINEERING CO., LTD., TIANJIN (CN); CCCC TIANJIN HARBOR ENGINEERING DESIGN INSTITUTE CO., LTD., Tianjin (CN)

(72) Inventors: Zengjun LI, TIANJIN (CN); Wei PAN, TIANJIN (CN); Zhipu LI, TIANJIN (CN); Weiwei ZHU, TIANJIN (CN); You WU, TIANJIN (CN); Shiyu WANG, TIANJIN (CN); Naishou ZHANG, TIANJIN (CN); Xiangyu LIU, TIANJIN (CN); Peng JU, TIANJIN (CN); Yi LIU, TIANJIN (CN); Wei LI, TIANJIN (CN); Hao DAI, TIANJIN (CN); Jianbo HAN, TIANJIN (CN)

(21) Appl. No.: 19/248,463

(22) Filed: Jun. 25, 2025

Related U.S. Application Data
(63) Continuation of application No. PCT/CN2024/070051, filed on Jan. 2, 2024.

(30) Foreign Application Priority Data
Sep. 20, 2023 (CN) 202311210942.8

(51) Int. Cl. G06F 30/23; G06F 30/13

(52) U.S. Cl. CPC G06F 30/23; G06F 30/13

(57) ABSTRACT

The present application relates to a BIM-based hanging basket design method, computer device and computer-readable storage medium, wherein the design method comprises following steps: a parameter acquisition step; a hanging basket modularization step: decomposing structures of hanging baskets into a plurality of design modules; a selection step; a calculation step: calculating parameters of the design modules using a structural mechanics calculation method and/or a finite element calculation method; preliminary BIM model building step: building models of the design modules and a preliminary BIM model of the hanging basket; an optimization iteration step: converting the preliminary BIM model of the hanging basket into a finite element model for calculation, and feeding calculation results back to the preliminary BIM model for structural adjustment, repeatedly performing iterative calculations to obtain optimized hanging basket parameter data; final BIM model acquisition step: the BIM model of the hanging basket adjusted according to the optimized hanging basket parameter data is a final BIM model of the hanging basket. The design method enables autonomous calculation and design of the hanging basket with good versatility.

This application is a continuation of the international application PCT/CN2024/070051, filed on Jan. 2, 2024, which claims priority to Chinese patent application 202311210942.8 filed on Sep. 20, 2023 and entitled “BIM-based Hanging Basket Design Method, Computer Device and Computer-readable Storage Medium”, the entire contents of the above identified applications are incorporated herein by reference.

### TECHNICAL FIELD

The present application relates to the field of construction engineering, and in particular to a BIM-based hanging basket design method, computer device and computer-readable storage medium.

### BACKGROUND ART

The global construction industry has widely recognized that BIM (Building Information Modeling) is the future development trend. The application of BIM technology in construction companies has been popularized to a certain extent. A large number of application points have been maturely developed in terms of engineering quantity calculation, collaborative management, in-depth design, virtual construction, resource planning, engineering archives and information integration. However, it can be seen that the application content of BIM has not been fully explored yet.

As one of the most widely used software in BIM system, although Revit is already powerful enough it still has many imperfections. In this regard, foreign countries have carried out research on the secondary development of Revit. Although domestic efforts are also underway, due to a relatively late start, due to the late start, current developments are mainly scattered across a few areas such as structural analysis, construction management, and simplified model creation.

In the construction of continuous beams, hanging basket construction is a relatively important construction method. Hanging basket construction is specifically applied to cast long-span cantilever beam bridges, utilizing a hanging basket system to perform segmented cantilever constructions. Hanging basket construction does not require scaffolding or large cranes. Compared with other methods, it has the advantages of lightweight structure, easy to assemble, and no need for counterweights.

The hanging basket is a large-scale construction tooling with a complex structure, numerous components, making the calculation extremely difficult. In traditional hanging basket design, the following steps are required: scheme selection→design drafting→manual preparation of calculation reports→drawing of detailed fabrication drawings of the hanging basket→processing by the formwork factory, which requires professional designers and usually takes several days to complete.

Due to the diverse structures of continuous beams, the structures of hanging baskets are even more varied. Although the overall structures of the hanging baskets are similar, there are more or less differences in structures of the continuous beams and hanging basket between different projects. Moreover, with the continuous upgrading of the cantilever casting construction techniques, the structures of the hanging baskets will gradually change. Therefore, a single calculation program is difficult to address all problems, making the research and development process extremely difficult.

In addition, most of the hanging baskets are currently rented. In order to facilitate fabrication, manufacturers often overlook the analysis of the rationality of force in the structural design of the hanging basket, resulting in an unreasonable structure and safety risks.

The traditional hanging basket design method mainly adopts manual calculations and experience accumulation, which has the following shortcomings:
(1) The design process is complex and inefficient, and the calculation process is often not accurate enough;
(2) It is difficult to ensure structural stability and rationality;
(3) The lack of a visualized design model makes it difficult to intuitively present the overall structure of the hanging basket.

### SUMMARY

In view of at least one shortcoming existing in the prior art, the present application provides a BIM-based hanging basket design method, a computer device and a non-transitory computer-readable storage medium.

In a first aspect, the present application provides a hanging basket design method based on building information modeling (BIM), wherein a hanging basket is used to construct a continuous beam, the design method comprising following steps:
a parameter acquisition step: acquiring parameters required for hanging basket design;
a hanging basket modularization step: decomposing structures of hanging baskets into a plurality of individual design modules, wherein hanging baskets of different structures are capable of being formed by selecting and combining specific design modules from the design modules;
a selection step: according to a structure of the continuous beam, selecting a structure of the hanging basket and required design modules, which are adapted to the structure of the continuous beam;
a calculation step: according to the parameters required for the hanging basket design acquired in the parameter acquisition step, calculating parameters of the required design modules using a structural mechanics calculation method and/or a finite element calculation method;
a preliminary BIM model building step: building models of the required design modules and a preliminary BIM model of the hanging basket based on calculated parameters of the required design modules;
an optimization iteration step: converting the preliminary BIM model of the hanging basket into a finite element model for calculation, and feeding calculation results back to the preliminary BIM model of the hanging basket for structural adjustment, repeatedly performing iterative calculations, and selecting a calculation result with a lowest cost as optimized hanging basket parameter data, on condition that structural design specifications of the hanging basket are satisfied;
a final BIM model acquisition step: adjusting the preliminary BIM model of the hanging basket according to the optimized hanging basket parameter data to obtain a final BIM model of the hanging basket.

In a second aspect, the present application provides a computer device, comprising:
at least one processor;
a memory, and
program instructions stored in the memory, when the program instructions are executed by the at least one processor, implementing the hanging basket design method based on BIM according to the first aspect.

In a third aspect, the present application provides a non-transitory computer-readable storage medium having program instructions stored thereon, when the program instructions are executed by at least one processor, implementing the hanging basket design method based on BIM according to the first aspect.

Compared with the related art, the BIM-based hanging basket design method, computer device and computer-readable storage medium provided in at least one embodiment of the present application, utilizes BIM technology for design and modeling, performs modular decomposition for the hanging basket, and carries out the design and calculation of the required hanging basket based on the continuous beam model, thereby improving the adaptability of the hanging basket to the continuous beam, enabling autonomous calculation and design of the hanging basket, minimizing manual intervention, building a complete visual three-dimensional model of the hanging basket, shortening the design cycle and reducing costs of the hanging basket, and having good versatility, and being applicable to the design of hanging baskets required for the construction of various types of continuous beams.

### BRIEF DESCRIPTION OF THE DRAWINGS

The accompanying drawings described herein are used to provide a further understanding of the present application and constitute a part of the present application. The exemplary embodiments of the present application and their descriptions are used to explain the present application and do not constitute an improper limitation on the present application. In the drawings:

FIG. 1 is a flow chart of a BIM-based hanging basket design method provided in an embodiment of the present application;

FIG. 2 is a schematic structural diagram of a single-cell continuous beam (one-half) in an embodiment of the present application;

FIG. 3 is a schematic structural diagram of a beam segment of the single-cell continuous beam in the embodiment of the present application;

FIG. 4 is a schematic structural diagram of a rhombus type hanging basket in an embodiment of the present application;

FIG. 5 is a schematic diagram of modular decomposition of a hanging basket in an embodiment of the present application;

FIG. 6 is a schematic diagram of decomposition of a formwork system in an embodiment of the present application;

FIG. 7 is a schematic structural diagram of a suspension system in an embodiment of the present application;

FIG. 8 is a schematic diagram of decomposition of the suspension system in an embodiment of the present application;

FIG. 9 is a schematic diagram of decomposition of a main truss system in an embodiment of the present application;

FIG. 10 is a schematic structural diagram of a traveling system in an embodiment of the present application;

FIG. 11 is a schematic diagram of decomposition of the traveling system in an embodiment of the present application;

FIG. 12 is a schematic structural diagram of an anchoring system in an embodiment of the present application;

FIG. 13 is a schematic diagram of decomposition of the anchoring system in an embodiment of the present application;

FIG. 14 is a schematic diagram of decomposition of a safety protection system in an embodiment of the present application;

FIG. 15 is a three-dimensional diagram of a final BIM model of the hanging basket built in an embodiment of the present application;

FIG. 16 is a schematic structural diagram of a computer device in an embodiment of the present application.

In the figures:
1, single-cell continuous beam; 11, beam segment; 111, bottom plate; 112, web plate; 113, flange plate; 114, top plate; 115, upper toothed block; 116, lower toothed block; 117, transverse diaphragm; 2, hanging basket; 21, formwork system; 211, bottom formwork; 212, side formwork; 213, core formwork; 214, inner/outer slide beams; 22, suspension system; 221, upper crossbeam; 222, upper hanger; 223, middle hanger; 224, lower hanger; 225, front support beam; 226, hanger adjustment support; 227, hanger bracket; 23, main truss system; 231, main truss; 232, middle portal frame; 233, node box; 24, traveling system; 241, back-locking roller device; 242, traveling track; 243, traveling track pad beam; 244, sliding support; 25, anchoring system; 251, rear anchor beam; 252, rear anchor adjustment beam; 253, rear anchor rod; 254, main truss lower chord; 255, back-locking or positive-pressing roller device; 256, traveling track beam; 257, anchor reinforcement; 26, safety protection system; 261, top of main truss; 262, top of upper crossbeam; 263, external safety protections at front and rear support beams; 264, up-down safety passage; 265, maintenance platform; 266, temporary ladder; 27, auxiliary component system; 30, bus; 31, processor; 32, memory; 33, communication interface.

### DETAILED DESCRIPTION OF EMBODIMENTS

In order to make the purpose, technical solutions and advantages of the present application clearer, the present application is described and illustrated below in conjunction with the accompanying drawings and embodiments. It should be understood that the specific embodiments described herein are only used to explain the present application and are not intended to limit the present application. Based on the embodiments provided in the present application, all other embodiments obtained by those of ordinary skill in the art without making creative work are within the scope of protection of the present application.

Apparently, the accompanying drawings in the following description are merely some of the examples or embodiments of the present application. For those of ordinary skill in the art, without paying any creative effort, the present application can also be applied to other similar circumstances according to these accompanying drawings. In addition, it should also be understood that, although the effort made in the development process may be complicated and tedious, for those of ordinary skill in the art related to the disclosure of the present application, some modifications in design, manufacture or production based on the technical contents disclosed by the present application are merely conventional technical means, and it should not be understood that the disclosure of the present application is insufficient.

The term “embodiment” herein means that specific features, structures or characteristics described with reference to an embodiment can be included in at least one embodiment of the present application. The appearance of “embodiment” in various locations of the description neither necessarily refers to the same embodiment, nor means an independent or alternative embodiment that is mutually exclusive with other embodiments. It should be explicitly and implicitly understood by those skilled in the art that an embodiment can be combined with other embodiments if not conflicted.

Unless otherwise defined, the technical terms or scientific terms involved in the present application should have their ordinary meanings as understood by a person of ordinary skill in the technical field to which the present application pertains. Similar words such as “a”, “an”, “one” and “the” involved in the present application do not mean any quantity limitation, and may mean a singular or plural form. The terms such as “include”, “comprise” and “have” and variants thereof involved in the present application are intended to cover non-exclusive inclusion. For example, a process, method, system, product or device including a series of steps or modules (units) is not limited to the listed steps or units, and may optionally include steps or units that are not listed or optionally include other steps or units intrinsic to this process, method, product or device. The term “a plurality of” involved in the present application means two or more.

It is worth understanding that the specific order of steps of a method may be shown in the present application, but the order of the steps may also be different from the described order. Furthermore, two or more steps can be performed at the same time or partially performed at the same time. All such variations fall within the scope of the present disclosure.

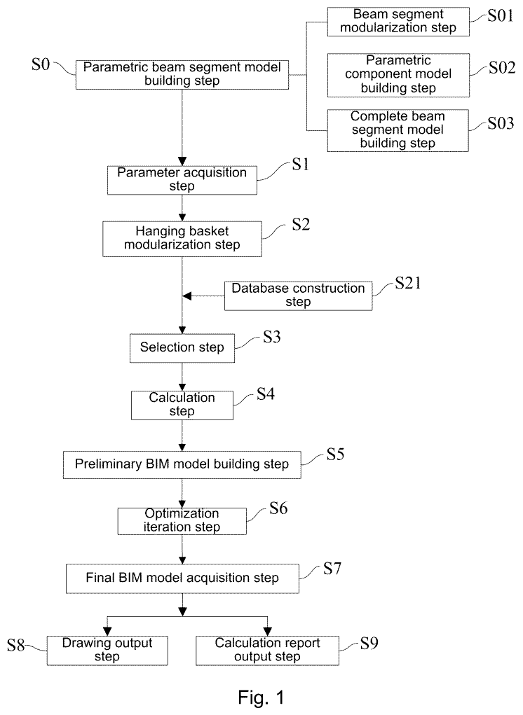

An embodiment of a first aspect of the present application provides a hanging basket design method based on building information modeling (BIM), wherein a hanging basket is used to construct a continuous beam. FIG. 1 is a flow chart of the hanging basket design method based on BIM according to the embodiment of the present application. As shown in FIG. 1, the design method comprises following steps:
S1 parameter acquisition step: acquiring parameters required for hanging basket design;
S2 hanging basket modularization step: decomposing structures of hanging baskets into a plurality of individual design modules, wherein hanging baskets of different structures are capable of being formed by selecting and combining specific design modules from the plurality of design modules;
S3 selection step: according to a structure of the continuous beam, selecting a structure of the hanging basket and required design modules, which are adapted to the structure of the continuous beam;
S4 calculation step: according to the parameters required for the hanging basket design acquired in the parameter acquisition step, calculating parameters of the required design modules using a structural mechanics calculation method and/or a finite element calculation method;
S5 preliminary BIM model building step: building models of the required design modules and a preliminary BIM model of the hanging basket based on calculated parameters of the required design modules;
S6 optimization iteration step: converting the preliminary BIM model of the hanging basket into a finite element model for calculation, and feeding calculation results back to the preliminary BIM model of the hanging basket for structural adjustment, repeatedly performing iterative calculations, and selecting a calculation result with a lowest cost as optimized hanging basket parameter data, on condition that structural design specifications of the hanging basket are satisfied;
S7 final BIM model acquisition step: adjusting the BIM model of the hanging basket according to the optimized hanging basket parameter data to obtain a final BIM model of the hanging basket.

Due to the diverse structures of continuous beams, the structures of the hanging baskets are even more varied. Although the overall structures of the hanging baskets are similar, there are more or less differences in structures of the continuous beams and the hanging baskets between different projects. A single calculation program is difficult to address all problems, making the design process of the hanging basket extremely difficult. The embodiments of the present application solve the above problems through a modular approach, enabling the design method to have sufficient versatility.

The BIM-based hanging basket design method provided by the above-mentioned embodiment of the present application, utilizes BIM technology for design and modeling, and adopts modular decomposition for the hanging basket, decomposing the structures of the hanging baskets into multiple design modules. During the design process, hanging baskets of various structures can be obtained by combining the constructed multiple design modules through different combination schemes and combination methods, which can basically cover the hanging basket structures commonly used in engineering. It has strong versatility and can be applied to the design of hanging baskets required for the construction of various types of continuous beams. The design method can be executed by a computer, can realize autonomous calculation and design of the hanging basket, minimizing manual intervention and avoid the complexity of manual calculation, and acquiring optimized hanging basket parameter data through iterative calculation, on condition that the design specifications are satisfied, the design scheme with the lowest cost is obtained, and a complete visualized three-dimensional model of the hanging basket is built, so as to improve the reliability and economy of the hanging basket design, and shorten the cycle and costs of the hanging basket design.

The hanging basket first needs to be adapted to the continuous beam to be constructed. The parameters required for the hanging basket design can be obtained based on the design drawings and construction requirements of the continuous beam. However, in order to improve accuracy of the hanging basket design and convenience of acquisition of the parameters required for the hanging basket design, in some embodiments, the hanging basket design method further comprises parametric beam segment model building step S0: acquiring parameters of the continuous beam based on design drawings of the continuous beam, inputting the parameters of the continuous beam to build parametric BIM models of beam segments of the continuous beam; in the parameter acquisition step, the parameters required for the hanging basket design are directly acquired from the parametric BIM models of the beam segments.

In the process of building the parametric BIM models of the beam segments according to a BIM modeling method, calculations and modeling relying on BIM technology to directly acquire model data. Since the beam segments must be parameterized, building an overall model is extremely difficult to generalize and it is also more difficult to acquire data from the overall model. Therefore, in some embodiments, the modeling method for the BIM models of the beam segments is optimized.

After optimization, the parametric beam segment model building step S0 comprises:
S01 beam segment modularization step: decomposing the beam segments into a plurality of components;
S02 parametric component model building step: building parametric component models for the components;
S03: complete beam segment model building step: inputting parameters into the parametric component models to generate the parametric BIM models of the beam segments.

The above embodiments of the present application upgrade and optimize the modeling method of the continuous beam, establishing the idea of modeling the continuous beam by components. By decomposing the continuous beam into individual components, and sequentially building the parametric component models and the parametric beam segment models, which can facilitate data reading, quickly build the BIM model of the continuous beam, and improve the versatility of the modeling method.

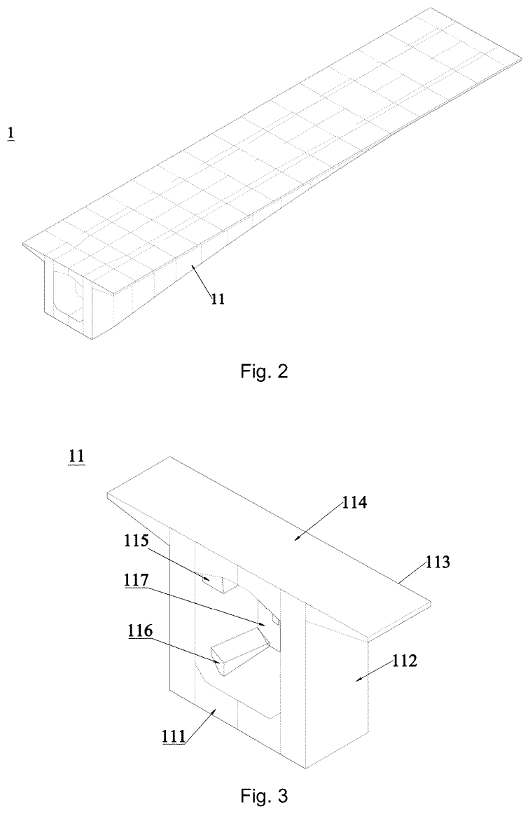

The structures of continuous beams include single-cell, double-cell, triple-cell, and other configurations. FIG. 2 is a schematic structural diagram of a single-cell continuous beam 1 (only half of the beam is shown in the figure and the other half is symmetrically arranged). The continuous beam 1 is formed by splicing multiple beam segments 11. As shown in FIG. 3, in a modular scheme of a beam segment of the single-cell continuous beam 1, the beam segment 11 can be decomposed into at least a bottom plate 111, a web plate 112, a flange plate 113, a top plate 114, toothed blocks (an upper toothed block 115 and a lower toothed block 116), a transverse diaphragm 117 and other components, each kind of components has various styles. For example, the web plate includes multiple styles such as “inclined web plate with rounded corners” and “straight web plate with chamfers”. Each component of different styles constitutes a component module, for which a corresponding parametric model is built. In addition, the parametric component models of the continuous beam can also be stored in a database, which facilitate direct use in subsequent hanging basket designs. Once the parametric component models are stored, required component models can be selected from the database for splicing as needed during future designs. Furthermore, commonly used parametric BIM models of the beam segments that have been spliced can also be stored in the database, allowing direct invocation of required BIM models of the beam segments during future designs.

In the parametric beam segment model building step S0, parametric modeling software can be used for modeling, and specific modeling methods can be implemented by those skilled in the art with reference to the prior art. The parametric modeling software may employ Revit software, but is not limited thereto; any software capable of achieving the same or similar functions may be used. In the parametric component model building step S02, the origins of the component models may be kept consistent and the parameter rules may be unified. During the parameter assignment process, the parameters of the continuous beam may be organized into a data file according to the design drawings of the continuous beam and directly input into the parametric modeling software, and the parametric BIM models of the beam segments can be quickly and automatically generated.

When the parametric BIM models of the beam segments are built, in the parameter acquisition step S1, the parameters required for the hanging basket design can be directly acquired from the built BIM models of the beam segments. These parameters comprise but are not limited to: geometric dimension parameters, mechanical index parameters, external load parameters, natural environmental condition parameters and material performance index parameters.

In some embodiments, in the parameter acquisition step S1, a beam segment under a most unfavorable loading condition for a currently designed component in the BIM models of the beam segments is determined through force analysis, and parameters of a BIM model of the beam segment under the most unfavorable loading condition are obtained for subsequent hanging basket design. The parameters required for the hanging basket design can be directly obtained from the BIM model of the beam segment under the most unfavorable loading condition. During the construction of the continuous beam, the continuous beam is divided into multiple beam segments for construction. The main function of the hanging basket is to use a cantilever method to construct each beam segment. Therefore, the hanging basket design may consider the most unfavorable loading condition of the beam segments for the construction. For example, based on the built parametric component models, the part with maximum bending moment and centroid of each component (for example, the bottom plate 111, the web plate 112, the flange plate 113, the top plate 114, the toothed block, and the transverse diaphragm 17) are respectively calculated to determine the beam segment under the most unfavorable loading condition (usually the beam segment with the maximum bending moment), and the calculations of the hanging basket design is performed based on the parameters of the BIM model of the beam segment under the most unfavorable loading condition.

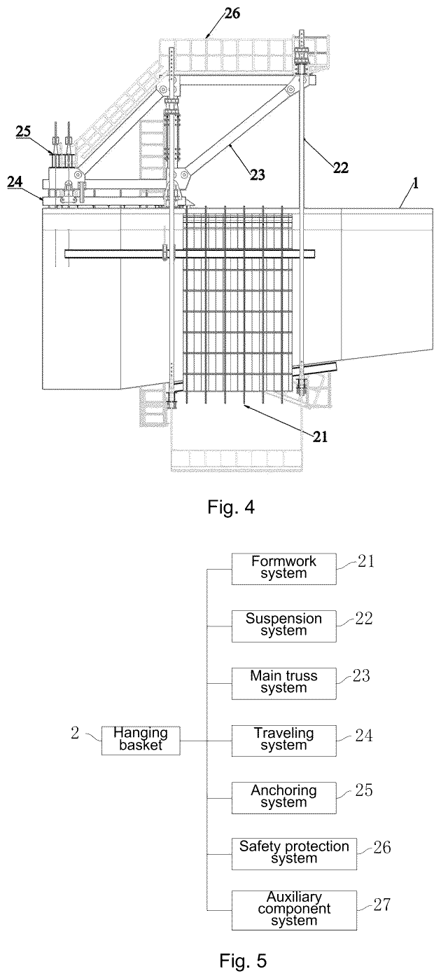

There are various structural forms of hanging baskets, which can be classified according to the structural forms, including: steel-girder type hanging baskets, truss type hanging baskets, cable-stayed type hanging baskets, bowstring type hanging baskets, sliding cable-stayed type hanging baskets, rhombus type hanging baskets, etc. Among them, the rhombus type hanging basket is most commonly used. FIG. 4 is a schematic structural diagram of a rhombus type hanging basket.

In some embodiments, in the hanging basket modularization step S2, as one of the decomposition schemes for the hanging basket, as shown in FIGS. 4 and 5, the hanging basket 2 is decomposed into at least a formwork system 21, a suspension system 22, a main truss system 23, a traveling system 24 and an anchoring system 25. It should be understood that in some embodiments, other systems may also included, such as a safety protection system 26 and an auxiliary component system. It should be understood that FIG. 4 only shows a part of the single-cell continuous beam 1 rather than the complete structure, which is only intended to illustrate the coordination between the hanging basket 2 and the single-cell continuous beam 1.

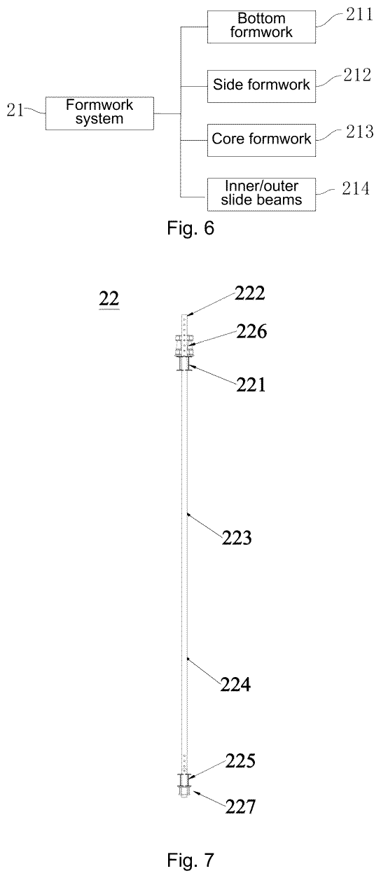

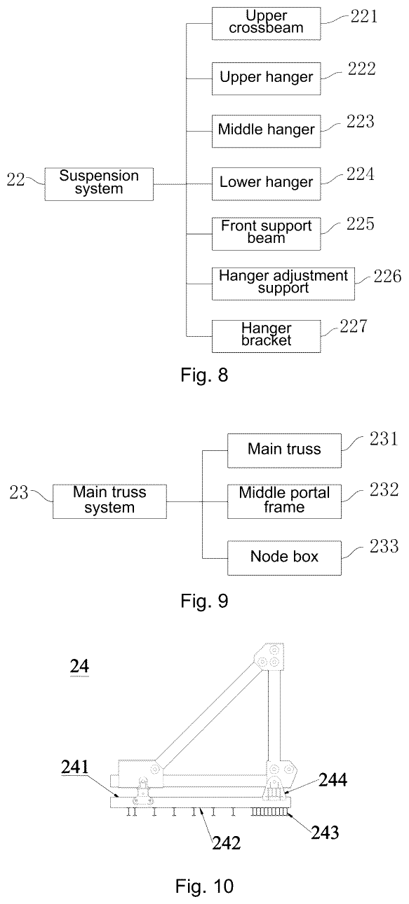

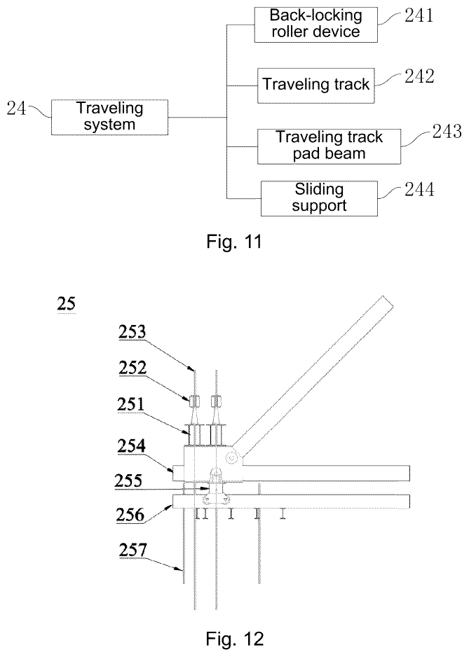

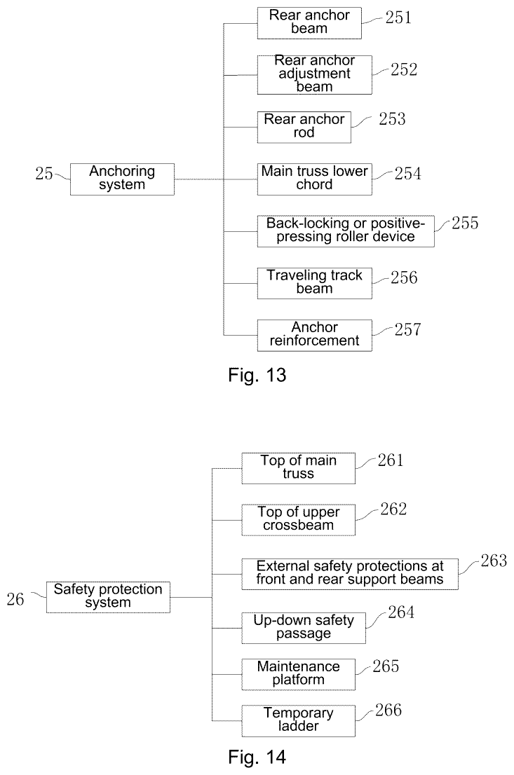

Each system comprises a variety of different components. For example, as shown in FIG. 6, the formwork system 21 is decomposed into at least: a bottom formwork 211, a side formwork 212, a core formwork 213, inner/outer slide beams 214, etc. As shown in FIGS. 7 and 8, the suspension system 22 is decomposed into at least: an upper crossbeam 221, hangers (including an upper hanger 222, a middle hanger 223, a lower hanger 224), a front support beam 225, a hanger adjustment support 226, a hanger bracket 227, etc. As shown in FIG. 9, the main truss system 23 is decomposed into at least: a main truss 231, a middle portal frame 232, a node box 233, etc. As shown in FIGS. 10 and 11, the traveling system 24 is decomposed into at least: a back-locking roller device 241, a traveling track 242, a traveling track pad beam 243, a sliding support 244, etc. As shown in FIGS. 12 and 13, the anchoring system 25 is decomposed into at least: a rear anchor beam 251, a rear anchor adjustment beam 252, a rear anchor rod 253, a main truss lower chord 254, a back-locking or positive-pressing roller device 255, a traveling track beam 256, an anchor reinforcement 257, etc. As shown in FIG. 14, the safety protection system 26 is decomposed into at least: a top of the main truss 261, a top of the upper crossbeam 262, external safety protections 263 at front and rear support beams, an up-down safety passage 264, a maintenance platform 265, a temporary ladder 266, etc. The specific structures of the above-mentioned components of the hanging basket may refer to the prior art, and will not be described in detail in this application.

In addition, each component comprises various part units. In the hanging basket modularization step S2, each component comprises multiple part units of different forms. For example, the bottom formwork, side formwork and core formwork in the formwork system of the hanging basket comprise part units such as panels, longitudinal ribs, cross beams, longitudinal beams and trusses. In some embodiments, the systems of the hanging basket are divided into 98 part units, and some of the part units are shown in Table 1.

TABLE 1
some of the part units and materials in the database

| Numbers | Systems | Components | Part Units | | Materials |
|---|---|---|---|---|---|
| 1 | Formwork | Bottom Formwork | Panel | | Steel Plate |
| 2 | System | | Cross Beam | | Angle Steel |
| | | | | | Channel Steel |
| 3 | | | Longitudinal Rib | | Steel Strip |
| 4 | | | Longitudinal Beam | | Channel Steel |
| 5 | | | Bottom Support Longitudinal Beam | | I-beam |
| 6 | | Core Formwork | Panel | | Steel Plate |
| 7 | | | Longitudinal Rib | | Steel Strip |
| 8 | | | Cross Beam | | Angle Steel |
| | | | | | Channel Steel |
| 9 | | | Truss | Top Chord | Channel Steel |
| 10 | | | | Bottom Chord | Channel Steel |
| 11 | | | | Vertical Web | Channel steel/ |
| 12 | | | | Diagonal Web | Angle Steel |
| 13 | | | | End Stud | Channel Steel |
| 14 | | | Connecting Rod | | |
| 15 | | | Inner Slide Beam | | Channel Steel |
| 16 | | | Inner Slide Beam Connection Plate | | Steel Plate |
| 17 | | | Toothed Block | Panel | Steel Plate |
| | | | | | Bamboo Plywood |
| 18 | | | | Transverse | Steel Strip |
| | | | | Rib | Square Timber |
| 19 | | | | Longitudinal | Angle Steel |
| | | | | Beam | Square Timber |
| 20 | | External Formwork | Panel | | Steel Plate |
| 21 | | | Longitudinal Rib | | Steel Strip |
| 22 | | | Cross Beam | | Angle Steel |
| 23 | | | Truss | Top Chord | Channel Steel |
| 24 | | | | Bottom Chord | Channel Steel |
| 25 | | | | Vertical Web | Channel steel/ |
| 26 | | | | Diagonal Web | Angle Steel |
| 27 | | | | End Stud | Channel Steel |
| 28 | | | Outer Slide Beam | | Channel Steel |
| 29 | Suspension | Front suspension | Front Support Beam | | Channel Steel |
| | System | | | | I-beam |
| 30 | | | Front Cross Beam | | Channel Steel |
| | | | | | I-beam |
| 31 | | | Front Suspension | Long | Precision- |
| 32 | | | Rod | Short | Rolled |
| | | | | | Threaded Bar |
| 33 | | | Front Suspension Rod Coupler | | Steel Plate |
| 34 | | | Front Suspension Rod Pin Shaft | | / |
| 35 | | | Precision-Rolled Threaded Bar | | / |
| | | | Coupler | | |
| 36 | | | Jack Reaction Beam | | / |
| 37 | | | Upper Jack for Front Suspension | | / |
| | | | Rod | | |
| 38 | Suspension | Rear Suspension | Rear Support Beam | | / |
| 39 | System | | Hanging Frame | Top Chord | Channel Steel |
| 40 | | | | Bottom Chord | Channel Steel |
| 41 | | | | Vertical Web | Channel steel/ |
| 42 | | | | Diagonal Web | Angle Steel |
| 43 | | | | End Stud | Channel Steel |
| 44 | | | Rear Suspension | Long | Precision- |
| | | | Rod | Short | Rolled |
| 45 | | | | | Threaded Bar |
| 46 | | | Rear Suspension Rod Backing Plate | | Steel Plate |
| 47 | | | Side Plate of Rear Suspension Rod | | Steel Plate |
| | | | Inner Slide Beam Hanger | | |
| 48 | | | Side Plate of Rear Suspension Rod | | Steel Plate |
| | | | Outer Slide Beam Hanger | | |
| 49 | Main Truss | Main truss | Upper Crossbeam | | Channel steel/ |
| 50 | System | | Lower Crossbeam | | I-beam |
| 51 | | | Vertical Rod | | |
| 52 | | | Front Diagonal Rod | | |
| 53 | | | Rear Diagonal Rod | | |
| 54 | | Node Box | Front Node Box | | Steel Plate |
| 55 | | | Rear Node Box | | |
| 56 | | | Upper Node Box | | |
| 57 | | | Lower Node Box | | |
| 58 | | Pin Shaft | / | | Alloy Steel Bar |
| 59 | | X-brace | / | | Channel Steel |
| | | | | | I-beam |
| 60 | Traveling | Back-locking | Back-locking Roller Pin Shaft | | Alloy Steel Bar |
| 61 | System | Components | Back-locking Roller Stiffening Rib | | Steel Plate |
| | | | Plate | | |
| 62 | | | Back-locking Roller Lug Plate | | Steel Plate |
| 63 | | | Back-locking Roller Fixing Base | | Steel Plate |
| 64 | | Traveling | Sliding Support | | Channel Steel |
| 65 | | Components | Traveling Track Beam | | I-beam |
| 66 | | | Jack Reaction Frame | | Steel Welding |
| 67 | | | Steel Sleeper | | I-beam |
| 68 | Anchoring | Anchor Structure | Anchor | Embedded | Precision- |
| | System | for Traveling | Reinforcement | Section | Rolled |
| 69 | | Condition | | Extension | Threaded Bar |
| | | | | Section | |

| | | | |
|---|---|---|---|
| 70 | Anchor Structure | Rear Anchor Beam | I-beam |
| 71 | for Fixed | Rear Anchor Tie Rod | Precision- |
| | Condition | | Rolled |
| | | | Threaded Bar |
| 72 | | Anchor Rod Pressure Plate | Steel Plate |
| 73 | | Precision-Rolled Threaded Bar | / |
| | | Coupler | |

Based on the modular decomposition of the hanging basket as described above, a database comprising systems, components and part units of the hanging basket can be constructed. In some embodiments, the hanging basket design method further comprises a database construction step S21: constructing a database comprising structural forms of the hanging baskets, component modules corresponding to respective components and part unit modules corresponding to respective part units, wherein each of the component modules stores structural data and calculation data of a corresponding component, and each of the part unit modules stores a model, a structural form and parameters of a corresponding part unit.

In step S21, a huge database for hanging basket design is constructed, in which various structural forms of hanging baskets and various component modules and part unit modules decomposed from the hanging baskets are stored. The database can cover more than 30% of common structural forms of hanging baskets and the corresponding components and part units. In the process of hanging basket design, instead of rebuilding from scratch for each design, existing part units and component modules can be selected in the database according to the required structure of the hanging basket to assemble the hanging basket, which significantly improves design efficiency and shortens the design cycle.

In addition, in some embodiments, the database also comprises a material library storing information of commonly used materials for continuous beams and hanging baskets, such as concrete, round steel, precision-rolled threaded bars, steel plates, wooden boards, bamboo plywood, pipes, steel strips, channel steel, H-beams, I-beams, and angle steels, with the materials encoded and their performance parameter values embedded.

In each component module, the structural data stores structural parameters of the corresponding component, while the calculation data stores structural mechanics calculation formulas of the corresponding component. During subsequent calculation and modeling process, the data in the database can be directly retrieved. By decomposing the hanging basket structure into the smallest unit, each part unit can be standardized with specific models and parameters. During subsequent calculation and modeling process of the component, the part unit modules of the required models can be directly selected, and the designed component can be calculated and automatically modeled according to the parameters in the selected part unit modules.

By constructing a database that contains various part unit modules, component modules and a material library, the structures and calculations of hanging baskets in various structural forms are standardized. For the modules that already exist in the database, rapid calculations can be achieved in subsequent calculation and modeling processes simply by ensuring accurate parameter retrieval. In addition, modules in the database can be edited or added as needed.

In some embodiments, the structural data in the component module is stored and built using a substitute module modeling method. Specifically: in the database construction step S21, each component is represented by a structural framework modeled by axis lines; in the final BIM model acquisition step, the axis lines are replaced with actual structural models of respective components. When storing the structural forms of various components in the database, creating parametric models is difficult and time-consuming, and some structures cannot be created or the creation effect is not good enough if rely solely on parametric model. Therefore, the substitute module modeling method is developed. This method simplifies the creation and modification of the structural forms in the modules, shortens the time, and improves the efficiency.

In some embodiments, parametric modeling software is used to construct the database, and the structural data in each component module comprises a parametric model file and a calculation script file, wherein the parametric model file is used to store the structural forms, and the calculation script file is used to pass parameters. The parametric modeling software includes but is not limited to Revit, which relies on the Revit software platform to realize the construction of the database. The database is built on the Revit platform to enable convenience of built-in modules invocation and new modules addition, providing a basis for the modular solution. Methods for embedding modules, invoking modules, and generating models using Revit are known techniques and will not be described in detail in this application.

In some embodiments, the calculation data of the component modules with a two-dimensional structure stores structural mechanics calculation formulas, and the calculation data of the component modules with a three-dimensional structure stores a finite element method. The structural mechanics calculation formulas and the finite element methods are both known formulas and methods.

In some embodiments, parametric modeling software is used to parse the calculation script files, and the structural mechanics calculation formulas and the finite element calculation method are encapsulated into node packages to form a node library. During the calculation process, the corresponding calculation methods in the node library are invoked to perform calculations.

In some embodiments, finite element software is invoked for automatic finite element modeling and calculation of the component modules with a three-dimensional structure. The finite element software includes but is not limited to Robot finite element software. Robot finite element software itself contains rich interfaces. By using the Robot finite element software as the finite element computation core, and the computation core can be quickly integrated through programming.

Based on the database constructed above, in the optimization iteration step S6, part unit modules of different models are selected from the database, and calculations is performed by retrieving data in the component module of a currently designed component in the database based on the parameters of selected part unit modules, until the structural design specifications of the hanging basket and lowest cost are satisfied.

In some embodiments, the hanging basket adopts a parametric design. In the optimization iteration step S6, feature parameters of the structure of the hanging basket are extracted, and the finite element model of the hanging basket is constructed in a finite element system based on the feature parameters, and calculations are performed using the finite element model. The calculation results are extracted and pass back to the preliminary BIM model of the hanging basket in a form of parameters to realize parameter modifications. This process is iteratively repeated until the optimized hanging basket parameter data is obtained. In traditional hanging basket design, a preliminary hanging basket model is generally created in CAD or BIM software first, and then the structure is remodeled in finite element software for structural calculation. The calculation results are manually passed back to the CAD or BIM model for adjustments. In this process, the BIM model and the finite element model are two independent and non-interconnected models. In this embodiment, the information exchange and interaction between the BIM model and the finite element model are realized during the optimization process. The BIM model is modified and adjusted through finite element calculation, and there is no need to modify the BIM model and the finite element model separately, thereby improving the accuracy and efficiency of the calculation. It can be understood that the feature parameters refer to parameters that indicate the spatial structure, dimensions and position information of the hanging basket. For example, the feature parameters comprise the length of the upper crossbeam, the length of the lower crossbeam, the installation positions and quantities of the hangers in the suspension system, and other such parameters.

In the optimization iteration step S6, the structural design specifications of the hanging basket typically require that a safety factor

$$( \frac{\sum {M}_{bl . i}}{\sum {M}_{sl . i}} \geq 2 )$$

for anti-overturning check during concrete pouring is greater than or equal to 2, and the ratio of the total weight of the hanging basket to the weight of the concrete of the beam segment is 0.3˜0.5; wherein, ΣM_{bl.i} is a total standard moment that stabilizes the anchoring system; ΣM_{sl.i} is a total standard moment that causes failure of the anchoring system.

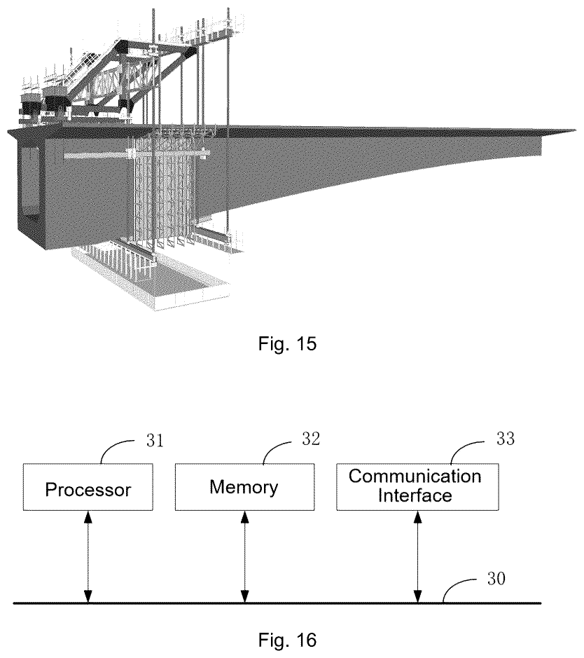

After the optimization iteration step, the optimized parameter data of the hanging basket is used to adjust the BIM model of the hanging basket to obtain the final BIM model of the hanging basket, as shown in FIG. 15.

In some embodiments, after the final BIM model acquisition step S7, the method further comprises a drawing output step S8: generating and outputting design drawings of the hanging basket based on the final BIM model of the hanging basket. The three-dimensional model can directly generate two-dimensional drawings as the final design drawings, which have strong versatility.

In some embodiments, after the final BIM model acquisition step S7, the method further comprises a calculation report output step S9: generating a corresponding calculation report based on entire calculation process of the hanging basket design. The calculation report can be automatically compiled by a computer without manual writing, saving time and effort.

In addition, the BIM-based hanging basket design method provided in the first aspect of the present application can be implemented by a computer device. FIG. 16 is a schematic structural diagram of a computer device according to an embodiment of the present application.

The computer device comprises at least one processor 31 and a memory 32 storing program instructions.

Specifically, the processor may include a Central Processing Unit (CPU), or an Application Specific Integrated Circuit (ASIC), or one or more integrated circuits configured to implement the embodiments of the present application.

The memory 32 may include a large-capacity storage device for data or instructions. By way of example and not limitation, the memory 32 may include a Hard Disk Drive (HDD), a floppy disk drive, a Solid State Drive (SSD), a flash memory, an optical disc, a magneto-optical disc, a magnetic tape, or a Universal Serial Bus (USB) drive, or a combination of two or more of these. Where appropriate, the memory 32 may be located inside or outside the data processing device. In specific embodiments, the memory 32 is a Non-Volatile memory. In specific embodiments, the memory 32 includes a Read-Only Memory (ROM) and a Random Access Memory (RAM). Where appropriate, the RAM may be a Static Random-Access Memory (SRAM) or a Dynamic Random Access Memory (DRAM), wherein the DRAM may be a Fast Page Mode Dynamic Random Access Memory (FPMDRAM), an Extended Data Out Dynamic Random Access Memory (EDODRAM), a Synchronous Dynamic Random-Access Memory (SDRAM), etc.

The memory 32 may be used to store or cache various data files required for processing and/or communication, as well as possible computer program instructions executed by the processor 31.

The processor 31 implements any one of the above-described embodiments of the hanging basket design method based on BIM by reading and executing the program instructions stored in the memory 32.

In some embodiments, the computer device may further comprise a communication interface 33 and a bus 30. As shown in FIG. 8, the processor 31, the memory 32, and the communication interface 33 are connected via the bus 30 to enable mutual communication.

The communication interface 33 is used to enable communication between the modules, devices, units and/or equipment in the embodiments of the present application. The communication interface 33 can also enable data communication with other components, such as external devices, image/data acquisition devices, databases, external storage and image/data processing workstations.

The bus 30 includes hardware, software or both, and couples the components of the computer device to each other. The bus 30 includes, but is not limited to, at least one of the following: a Data Bus, an Address Bus, a Control Bus, an Expansion Bus, and a Local Bus. By way of example and not limitation, the bus 30 may include an Accelerated Graphics Port (AGP) or other graphics bus, an Extended Industry Standard Architecture (EISA) bus, a Front Side Bus (FSB), a Hyper Transport (HT) interconnect, an Industry Standard Architecture (ISA) bus, an InfiniBand interconnect, a Low Pin Count (LPC) bus, a memory bus, a Micro Channel Architecture (MCA) bus, a Peripheral Component Interconnect (PCI) bus, a PCI-Express (PCI-X) bus, a Serial Advanced Technology Attachment (SATA) bus, a Video Electronics Standards Association Local Bus (VLB), or other suitable buses, or a combination of two or more of these. Where appropriate, the bus 30 may include one or more buses. Although the embodiments of the present application describe and illustrate specific buses, the present application contemplates any suitable bus or interconnection.

In addition, in combination with the hanging basket design method based on BIM in the above embodiments, an embodiment of the present application provides a computer-readable storage medium to implement the method. The computer-readable storage medium is a non-transitory computer-readable storage medium, which stores program instructions; when the program instructions are executed by at least one processor, any one of the above-described embodiments of the hanging basket design method is implemented.

The technical features of the above-described embodiments may be arbitrarily combined. For brevity, not all possible combinations of the technical features in the above-described embodiments are described. However, as long as the combinations of these technical features do not conflict with each other, they should be considered to be within the scope of this specification.

The above-described embodiments merely express several implementations of the present application, and the descriptions thereof are relatively specific and detailed, but they should not be interpreted as limiting the scope of the patent application. It should be pointed out that, for a person of ordinary skill in the art, several variations and improvements can be made without departing from the concept of the present application, and these all belong to the protection scope of the present application. Therefore, the protection scope of the patent application shall be subject to the appended claims.

1. A hanging basket design method based on building information modeling (BIM), wherein a hanging basket is used to construct a continuous beam, the hanging basket design method comprising following steps:
a parameter acquisition step: acquiring parameters required for hanging basket design;
a hanging basket modularization step: decomposing structures of hanging baskets into a plurality of individual design modules, wherein hanging baskets of different structures are capable of being formed by selecting and combining specific design modules from the design modules;
a selection step: according to a structure of the continuous beam, selecting a structure of the hanging basket and required design modules, which are adapted to the structure of the continuous beam;
a calculation step: according to the parameters required for the hanging basket design acquired in the parameter acquisition step, calculating parameters of the required design modules using a structural mechanics calculation method and/or a finite element calculation method;
a preliminary BIM model building step: building models of the required design modules and a preliminary BIM model of the hanging basket based on calculated parameters of the required design modules;
an optimization iteration step: converting the preliminary BIM model of the hanging basket into a finite element model for calculation, and feeding calculation results back to the preliminary BIM model of the hanging basket for structural adjustment, repeatedly performing iterative calculations, and selecting a calculation result with a lowest cost as optimized hanging basket parameter data, on condition that structural design specifications of the hanging basket are satisfied;
a final BIM model acquisition step: adjusting the preliminary BIM model of the hanging basket according to the optimized hanging basket parameter data to obtain a final BIM model of the hanging basket;
wherein the hanging basket adopts a parametric design, and in the optimization iteration step, extracting feature parameters of the structure of the hanging basket, and constructing the finite element model of the hanging basket in a finite element system based on the feature parameters, performing calculations using the finite element model, and extracting the calculation results and passing the calculation results back to the preliminary BIM model of the hanging basket in a form of parameters to realize parameter modifications, until the optimized hanging basket parameter data is obtained.

2. The hanging basket design method according to claim 1, wherein further comprises a parametric beam segment model building step: acquiring parameters of the continuous beam based on design drawings of the continuous beam, inputting the parameters of the continuous beam to build parametric BIM models of beam segments;
wherein, in the parameter acquisition step, the parameters required for the hanging basket design are acquired from the parametric BIM models of the beam segments.

3. The hanging basket design method according to claim 2, wherein the parametric beam segment model building step comprises:
a beam segment modularization step: decomposing the beam segments into a plurality of components;
a parametric component model building step: building parametric component models for the components;
a complete beam segment model building step: inputting parameters into the parametric component models to generate the parametric BIM models of the beam segments.

4. The hanging basket design method according to claim 1, wherein in the hanging basket modularization step, decomposing the hanging basket into at least a formwork system, a suspension system, a main truss system, a traveling system and an anchoring system, each system comprises a plurality of components of different types, and each component comprises a plurality of part units of different types.

5. The hanging basket design method according to claim 4, wherein further comprises a database construction step: constructing a database comprising structural forms of the hanging baskets, component modules corresponding to respective components and part unit modules corresponding to respective part units, wherein each of the component modules stores structural data and calculation data of a corresponding component, and each of the part unit modules stores a model, a structural form and parameters of a corresponding part unit; in the optimization iteration step, selecting part unit modules of different models from the database, and performing calculations by retrieving data in the component module of a currently designed component in the database based on the parameters of selected part unit modules, until the structural design specifications of the hanging basket and lowest cost are satisfied.

6. The hanging basket design method according to claim 5, wherein the structural data in the component modules is stored and built using a substitute module modeling method, specifically: in the database construction step, each component is represented by a structural framework modeled by axis lines for storage; in the final BIM model acquisition step, the axis lines are replaced with actual structural models of respective components.

7. The hanging basket design method according to claim 5, wherein the calculation data of the component modules with a two-dimensional structure stores structural mechanics calculation formulas, and the calculation data of the component modules with a three-dimensional structure stores a finite element method.

8. The hanging basket design method according to claim 1, wherein the parameters required for the hanging basket design acquired in the parameter acquisition step comprise: geometric dimension parameters, mechanical index parameters, external load parameters, natural environmental condition parameters and material performance index parameters.

9. The hanging basket design method according to claim 1, wherein, after the final BIM model acquisition step, the method further comprises following steps:
a drawing output step: generating and outputting design drawings of the hanging basket based on the final BIM model of the hanging basket;
a calculation report output step: generating a corresponding calculation report based on entire calculation process during the hanging basket design.

10. A computer device, comprising:
at least one processor;
a memory, and
program instructions stored in the memory, when the program instructions are executed by the at least one processor, implementing the hanging basket design method based on BIM according to claim 1.

11. A non-transitory computer-readable storage medium having program instructions stored thereon, when the program instructions are executed by at least one processor, implementing the hanging basket design method based on BIM according to claim 1.
